(19) United States
(12) Patent Application Publication
(10) Pub. No.: US 2026/0136514 A1
(43) Pub. Date: May 14, 2026

(54) Layout pattern of static random access memory and manufacturing method thereof

(71) Applicant: UNITED MICROELECTRONICS CORP., Hsin-Chu City (TW)

(72) Inventors: Shu-Wei Yeh, Tainan City (TW); Chang-Hung Chen, Tainan City (TW)

(73) Assignee: UNITED MICROELECTRONICS CORP., Hsin-Chu City (TW)

(21) Appl. No.: 18/973,122

(22) Filed: Dec. 9, 2024

(30) Foreign Application Priority Data
Nov. 14, 2024 (TW) 113143792

(51) Int. Cl. H10B 10/00

(52) U.S. Cl. CPC H10B 10/12

(57) ABSTRACT

The invention provides a layout pattern of static random access memory (SRAM) cell, which at least comprises an SRAM cell in a region, wherein the SRAM cell comprises a plurality of fin structures on a substrate, wherein a plurality of gate structures span the plurality of fin structures so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a pass gate transistor PG2B are located on the substrate, wherein the first pull-up transistor PU1 and the second pull-up transistor PU2 are aligned with each other in a Y direction when viewed from a top view.

### BACKGROUND OF THE INVENTION

### 1. Field of the Invention

The invention relates to the field of semiconductors, in particular to a static random access memory (SRAM) layout pattern and a manufacturing method thereof. The SRAM layout pattern provided by the invention has high symmetry, so it is helpful to reduce the difference value of the turn-on current of elements and improve the quality of elements.

### 2. Description of the Prior Art

An embedded static random access memory (embedded SRAM) includes a logic circuit and a static random access memory connected with the logic circuit. Static random access memory itself belongs to a volatile memory cell, that is, when the power supplied to static random access memory disappears, the stored data will be erased at the same time. Static random access memory (SRAM) stores data by using the conductive state of the transistors in the memory cell. The design of SRAM is based on mutually coupled transistors, which has no problem of capacitor discharge, and does not need to be continuously charged to keep the data from losing, that is, it does not need to update the memory, which is different from the Dynamic Random Access Memory (DRAM) which belongs to the volatile memory, which uses the charged state of the capacitor to store data. The access speed of static random access memory is quite fast, so it has applications as cache memory in computer systems.

### SUMMARY OF THE INVENTION

The invention provides a layout pattern of static random access memory (SRAM) cells, which at least comprises an SRAM cell in a region, wherein the SRAM cell comprises a plurality of fin structures located on a substrate, and the plurality of fin structures at least comprise a first fin structure, a second fin structure and a third fin structure arranged along a Y direction, a plurality of gate structures located on the substrate, and each gate structure extends along an X direction, wherein the gate structures include a first gate structure, a second gate structure, a third gate structure, a fourth gate structure, a fifth gate structure and a sixth gate structure, wherein the gate structures span the fin structures, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate, wherein when viewed from a top view, the first pull-up transistor PU1 and the second pull-up transistor PU2 are aligned with each other in the Y direction.

The invention also provides a method for manufacturing layout patterns of static random access memory (SRAM) cells, which at least comprises forming an SRAM cell in a region, wherein the SRAM cell comprises a plurality of fin structures located on a substrate, and the plurality of fin structures at least comprise a first fin structure, a second fin structure and a third fin structure arranged along a Y direction, a plurality of gate structures located on the substrate, and each gate structure extends along an X direction, wherein the gate structures include a first gate structure, a second gate structure, a third gate structure, a fourth gate structure, a fifth gate structure and a sixth gate structure, wherein the gate structures span the fin structures, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate, wherein when viewed from a top view, the first pull-up transistor PU1 and the second pull-up transistor PU2 are aligned with each other in the Y direction.

In one embodiment of the present invention, a layout pattern of SRAM cells with high symmetry is proposed, especially for each pass gate transistor, the surrounding environment of each pass gate transistor is approximately the same, for example, the distance from the fin structure spanned by each pass gate transistor to the adjacent fin structure is almost the same, so the current of each pass gate transistor of the SRAM of this embodiment approaches the same, which can improve the quality of the device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a circuit diagram of a set of eight-transistor dual port static random access memory (8TDP-SRAM) memory cells in the static random access memory of the present invention.

FIG. 2 is a layout diagram of a static random access memory according to the first embodiment of the present invention.

FIG. 3 is a layout diagram of a static random access memory according to a second embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,”“an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and metal layers (in which contacts, interconnect lines, and/or vias are formed) and one or more dielectric layers.

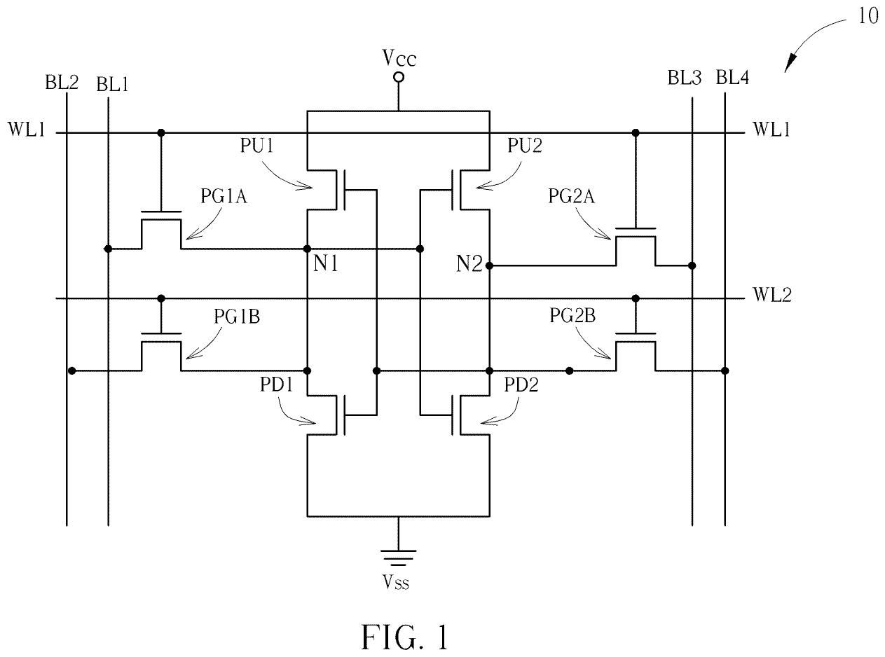

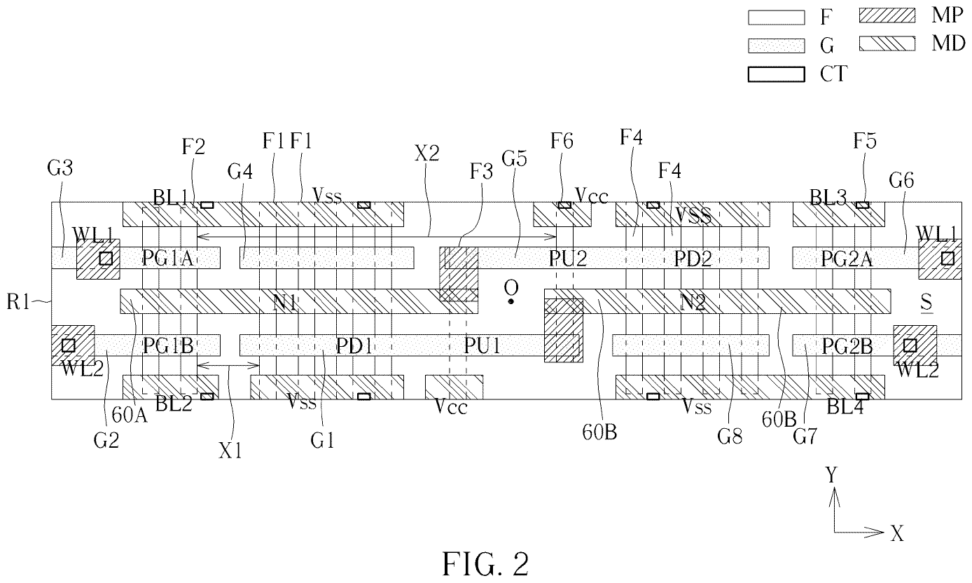

Referring to FIGS. 1-2, FIG. 1 illustrates a circuit diagram of an eight-transistor SRAM (8T-SRAM) cell according to a first preferred embodiment of the present invention, and FIG. 2 illustrates a layout diagram of an 8T-SRAM according to the first preferred embodiment of the present invention.

As shown in FIGS. 1-2, the SRAM device of the present invention preferably includes at least one SRAM cell, each SRAM cell including an eight-transistor dual port SRAM (8TDP-SRAM) cell 10.

In this embodiment, each 8TDP-SRAM cell 10 is composed of a first pull-up transistor PU1, a second pull-up transistor PU2, and a first pull-down transistor PD1, a second pull-down transistor PD2, a first pass gate transistor PG1A, a second pass gate transistor PG1B, a third pass gate transistor PG2A and a fourth pass gate transistor PG2B. These eight transistors constitute a set of flip-flops. The first and the second pull-up transistors PU1 and PU2, and the first and the second pull-down transistors PD1 and PD2 constitute a latch circuit that stores data in the storage nodes N1 and N2. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source (voltage node) Vcc, and the first and the second pull-down transistors PD1 and PD2 share a source/drain region and electrically connect to a voltage source (voltage node) Vss.

Preferably, the first and the second pull-up transistors PU1 and PU2 of the 8TDP-SRAM cell 10 are composed of p-type metal oxide semiconductor (PMOS) transistors; the first and the second pull-down transistors PD1 and PD2, the first pass gate transistors PG1A, the second pass gate transistors PG1B, the third pass gate transistors PG2A and the fourth pass gate transistors PG2B composed of n-type metal oxide semiconductor (NMOS) transistors, but not limited thereto. The first pull-up transistor PU1 and the first pull-down transistor PD1 constitute an inverter, which further form a series circuit. One end of the series circuit is connected to a voltage source Vcc and the other end of the series circuit is connected to a voltage source Vss. Similarly, the second pull-up transistor PU2 and the second pull-down transistor PD2 constitute another inverter and a series circuit. One end of the series circuit is connected to the voltage source Vcc and the other end of the series circuit is connected to the voltage source Vss. Each pass gate transistors (including the first pass gate transistor PG1A, the second pass gate transistor PG1B, the third pass gate transistor PG2A and the fourth pass gate transistor PG2B) configured with the two cross-coupled inverters respectively, wherein each of the at least one pull-up transistor (PLs), the at least one pull-down transistors (PDs), and the at least two pass gate transistor (PGs) includes a fin field-effect transistor (FinFET).

The storage node N1 is connected to the respective gates of the second pull-down transistor PD2 and the second pull-up transistor PU2. The storage node N1 is also connected to the drain of the first pull-down transistor PD1, the drain of the first pull-up transistor PU1, the drain of the first pass gate transistor PG1A and the drain of the second pass gate transistor PG1B. Similarly, the storage node N2 is connected to the respective gates of the first pull-down transistor PD1 and first the pull-up transistor PU1. The storage node N2 is also connected to the drain of the second pull-down transistor PD2, the drain of the second pull-up transistor PU2, the drain of the third pass gate transistor PG2A and the drain of the fourth pass gate transistor PG2B. The gates of the first pass gate transistor PG1A and the third pass gate transistor PG1B are respectively coupled to a first word line (WL1); the gates of the second pass gate transistor PG1B and the fourth pass gate transistor PG2B are respectively coupled to a second word line (WL2); the source of the first pass gate transistor PG1A is coupled to a first bit line (BL1); the source of the second pass gate transistor PG1B is coupled to a second bit line (BL2); the source of the third pass gate transistor PG2A is coupled to a third bit line (BL3); and the source of the fourth pass gate transistor PG2B is coupled to a fourth bit line (BL4).

Please refer to FIG. 2. In this embodiment, an 8TDP-SRAM memory cell 10 is located in a first region R1, and is disposed on a substrate S, such as a silicon substrate or a silicon-on-insulator (SOI) substrate. A plurality of fin structures F arranged in parallel are disposed on the substrate S, and shallow trench isolation (not shown) is provided around each fin structure F.

In addition, the substrate S includes a plurality of gate structures G. Each transistor (including the first pull-up transistor PU1, the first pull-down transistor PD1, the second pull-up transistor PU2, the second pull-down transistor PD2, the first pass gate transistor PG1A, the second pass gate transistor PG1B, the third pass gate transistor PG2A, and the fourth pass gate transistor PG2B) includes a gate structure G that spans at least one fin structure F to form each transistor.

As shown in FIG. 2, in order to clearly define the position of each gate structure G, the gate structures G are defined as a first gate structure G1, a second gate structure G2, a third gate structure G3, a fourth gate structure G4, a fifth gate structure G5, a sixth gate structure G6, a seventh gate structure G7 and an eighth gate structure G8. At the same time, the fin structures F are defined as fin structures F1, F2, F3, F4, F5 and F6 respectively according to their positions. It can be understood that the first gate structure G1 to the eighth gate structure G8 all belong to the gate structure G, and the fin structure F1 to the fin structure F6 also belong to the fin structure F. The first gate structure G1 spans the fin structure F1 to form a first pull-down transistor PD1, the first gate structure G1 spans the fin structure F3 to form a first pull-up transistor PU1, the second gate structure G2 spans the fin structure F2 to form a second pass gate transistor PG1B, the third gate structure G3 spans the fin structure F2 to form the first pass gate transistor PG1A, the fourth gate structure G4 spans the fin structure F1, but no transistor is formed at the intersection (because the fin structure F1 at its source terminal is not connected to the voltage source Vss), so the fourth gate structure G4 can be regarded as a dummy gate structure. On the other hand, the fifth gate structure G5 spans the fin structure F4 to form a second pull-down transistor PD2, the fifth gate structure G5 spans the fin structure F6 to form a second pull-up transistor PU2, the sixth gate structure G6 spans the fin structure F5 to form a third pass gate transistor PG2A, the seventh gate structure G7 spans the fin structure F5 to form a fourth pass gate transistor PG2B, the eighth gate structure G8 spans the fin structure F4, but no transistor is formed at the intersection (because the fin structure F4 at its source terminal is not connected to the voltage source Vss), so the eighth gate structure G8 can be regarded as a dummy gate structure.

It is worth noting that in the first region R1, the patterns of the transistors are mirror symmetrical along the center point O, so the features of the partially symmetrical elements in the following paragraphs will be the same as those of the other half, and will not be repeated here.

In the present invention, each gate structure G is arranged along a first direction (for example, X axis), and each fin structure F is arranged along a second direction (for example, Y axis). Preferably, the first direction and the second direction are perpendicular to each other.

The present invention also includes a first interconnection layer 60A and a second interconnection layer 60B, both of which are arranged along the first direction (X direction). In which the first interconnection layer 60A spans the fin structure F respectively included in the first pull-up transistor PU1, the first pull-down transistor PD1, the first pass gate transistor PG1A and the second pass gate transistor PG1B. The second interconnection layer 60B spans the fin structure F included in the second pull-up transistor PU2, the second pull-down transistor PD2, the third pass gate transistor PG2A and the fourth pass gate transistor PG2B.

In addition, the substrate S includes a plurality of metal layers MP, a metal layer MD and a contact plug CT, which connect different transistors (for example, connecting the gate of the second pull-up transistor PU2 and the drain of the first pull-up transistor PU1) or connecting each transistor to other elements (for example, connecting the source of the first pull-up transistor PU1 to the voltage source Vcc). In this embodiment, the metal layer MP contacts the gate structure G, while the metal layer MD spans the fin structure F but does not contact the gate structure G. The contact plug CT is used to connect the conductive elements of different layers (such as the current metal layer and other metal layers above/below). It can be understood that the metal layer MP, the metal layer MD and the contact plug CT can all be made of materials with good conductivity, such as metals, and may comprise the same or different materials. In addition, the first interconnection layer 60A and the second interconnection layer 60B also belong to the metal layer MD.

For the sake of clarity, in FIG. 2, elements (such as voltage source Vcc, voltage source Vss, first word line WL1, second word line WL2, first bit line BL1, second bit line BL2, third bit line BL3 and fourth bit line BL4) connected to each metal layer MP and MD are directly marked on each metal layer and contact plug CT to clearly express the connection between each metal layer MP and MD and contact plug CT.

In this embodiment, due to the design of the layout pattern, the surrounding environmental conditions of each pass gate transistor are slightly different, and the reading current and other parameters of each pass gate transistor are affected, and even the current asymmetry of the whole 8TDP-SRAM memory cell 10 may be caused. More specifically, as shown in FIG. 2, the right side of the second pass gate transistor PG1B includes the first pull-down transistor PD1, so the distance between the fin structure F2 spanned by the second pass gate transistor PG1B and the adjacent fin structure on the right side (that is, the fin structure F1 spanned by the first pull-down transistor PD1) is short, and the distance between the fin structure F2 and the fin structure F1 in the horizontal direction (X direction) is defined as X1. In addition, for the first pass gate transistor PG1A, there are only dummy transistors adjacent to the right side of the fin structure F2 spanned by the first pass gate transistor PG1A, so the distance between the fin structure F2 spanned by the first pass gate transistor PG1A and the fin structure F6 spanned by the second pull-up transistor PU2 is long, and the distance between the fin structure F2 and the fin structure F6 in the horizontal direction (X direction) is defined as X2. It is obvious from the figure that the distance X2 is greater than the distance X1. In some embodiments, the distance X1 is about 104 nm, while the distance X2 is about 432 nm. Therefore, for the first pass gate transistor PG1A and the second pass gate transistor PG1B, the reading current and other parameters of each pass gate transistor are affected due to different environmental conditions.

Similarly, because the layout pattern in FIG. 2 is symmetrical along the center point O, the reading current and other parameters of the third and fourth pass gate transistors PG2A and PG2B will be affected due to different environmental conditions.

In order to solve the above problems, in other embodiments of the present invention, a layout pattern of static random access memory cells is proposed, especially an eight-transistor dual port static random access memory (8TDP-SRAM) memory cell layout pattern. The circuit diagram is the same as the above-mentioned FIG. 1, so detailed description is not repeated. Another embodiment of the present invention is characterized in that the layout pattern has high symmetry, so the surrounding environment of each pass gate transistor is almost the same, and therefore the reading current of each pass gate transistor will be similar. This can improve the stability and quality of SRAM, as detailed in the following paragraph.

In the following, different embodiments of the present invention will be described, and in order to simplify the description, the following description will mainly focus on the differences of each embodiment, and will not repeat the similarities. In addition, the same elements in various embodiments of the present invention are labeled with the same reference numerals, so as to facilitate the comparison among various embodiments.

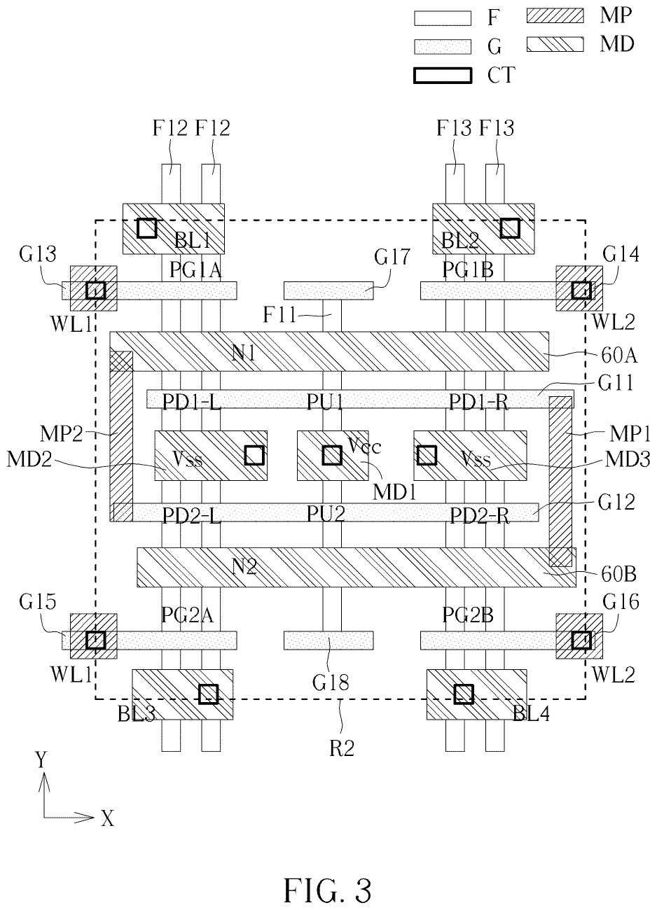

Please refer to FIG. 3, which is a layout diagram of a static random access memory according to the second embodiment of the present invention. As shown in FIG. 3, the substrate is provided with a plurality of fin structures F arranged in parallel with each other, and shallow trench isolation is arranged around each fin structure F (not shown). In addition, the substrate contains a plurality of gate structures G, and the transistors (including the first pull-up transistor PU1, the first pull-down transistor PD1, the second pull-up transistor PU2, the second pull-down transistor PD2, the first pass gate transistor PG1A, the second pass gate transistor PG1B, the third pass gate transistor PG2A, and the fourth pass gate transistor PG2B) all contain a gate structure G spanning at least one fin structure F, and form each transistor.

As shown in FIG. 3, in order to clearly define the position of each gate structure G, the gate structures G are respectively defined as a first gate structure G11, a second gate structure G12, a third gate structure G13, a fourth gate structure G14, a fifth gate structure G15, a sixth gate structure G16, a seventh gate structure G17 and an eighth gate structure G18. At the same time, the fin structures F are defined as fin structure F11, fin structure F12 and fin structure F13 according to its position. It can be understood that the first gate structure G11 to the eighth gate structure G18 all belong to the gate structure G, and the fin structure F1 to the fin structure F3 also belong to the fin structure F. The first gate structure G11 spans the fin structure F11 to form a first pull-up transistor PU1, the first gate structure G11 spans the fin structure F12 to form a left half first pull-down transistor PD1-L, and the first gate structure G11 spans the fin structure F13 to form a right half first pull-down transistor PD1-R, wherein the left half first pull-down transistor PD1-L and the right half first pull-down transistor PD1-R are located on the left and right sides of the first pull-up transistor PU1, respectively, and the left half first pull-down transistor PD1-L and the right half first pull-down transistor PD1-R are both part of the first pull-down transistor PD1.

The second gate structure G12 spans the fin structure F11 to form a second pull-up transistor PU2,the second gate structure G12 spans the fin structure F12 to form a left half second pull-down transistor PD2-L, and the second gate structure G12 spans the fin structure F13 to form a right half second pull-down transistor PD2-R, wherein the left half second pull-down transistor PD2-L and the right half second pull-down transistor PD2-R are located on the left and right sides of the second pull-up transistor PU2, respectively, and the left half second pull-down transistor PD2-L and the right half second pull-down transistor PD2-R are both part of the second pull-down transistor PD2.

In addition, the third gate structure G13 spans the fin structure F2 to form the first pass gate transistor PG1A, the fourth gate structure G14 spans the fin structure F3 to form a second pass gate transistor PG1B, the fifth gate structure G15 spans the fin structure F2 to form a third pass gate transistor PG2A, the sixth gate structure G16 spans the fin structure F3 to form the fourth pass gate transistor PG2B. The seventh gate structure G17 and the eighth gate structure G18 are located at the upper and lower ends of the fin structure F1 in the Y axis direction, respectively, wherein the seventh gate structure G17, the third gate structure G13 and the fourth gate structure G14 are aligned with each other in the X direction. In addition, the eighth gate structure G18 is aligned with the fifth gate structure G15 and the sixth gate structure G16. In the actual manufacturing process, a strip-shaped gate structure can be formed first, and then a cutting step can be performed to cut the strip-shaped gate structure into multiple segments, for example, a continuous gate structure can be cut into a third gate structure G13, a fourth gate structure G14 and a seventh gate structure G17. It is worth noting that the seventh gate structure G17 and the eighth gate structure G18 in this embodiment do not form transistors, so they can be regarded as dummy gate structures.

It is worth noting that in the region R2, the patterns of the transistors are mirror symmetrical along the center point, so the features of the partially symmetrical elements in the following paragraphs will be the same as those of the other half, and will not be repeated here.

In the present invention, each gate structure G is arranged along a first direction (for example, X axis), and each fin structure F is arranged along a second direction (for example, Y axis). Preferably, the first direction and the second direction are perpendicular to each other.

In addition, the substrate includes a plurality of metal layers MP, a metal layer MD and a contact plug CT, which connect different transistors (for example, connecting the gate of the second pull-up transistor PU2 and the drain of the first pull-up transistor PU1) or connecting each transistor to other elements (for example, connecting the source of the first pull-up transistor PU1 to the voltage source Vcc). In this embodiment, the metal layer MP directly contacts the gate structure G, while the metal layer MD spans the fin structure F but does not contact the gate structure G. The contact plug CT is used to connect different layers (for example, the current metal layer and other metal layers above/below). It can be understood that the metal layer MP, the metal layer MD and the contact plug CT are all used to connect different components, so they can all be made of materials with good conductivity, such as metals, and may contain the same or different materials.

The present invention also includes a first interconnection layer 60A and a second interconnection layer 60B, both of which are arranged along the first direction (X direction). The first interconnection layer 60A spans the fin structure F11, the fin structure F12 and the fin structure F13, and electrically connects the source/drain of the first pull-up transistor PU1, the left half first pull-down transistor PD1-L, the right half first pull-down transistor PD1-R, the first pass gate transistor PG1A and the second pass gate transistor PG1B. In addition, the first interconnection layer 60A is located between the first gate structure G11 and the third gate structure G13 (or the fourth gate structure G14). Similarly, the second interconnection layer 60B spans the fin structure F11, the fin structure F12 and the fin structure F13, and electrically connects the sources/drains of the second pull-up transistor PU2, the left half second pull-down transistor PD2-L, the right half second pull-down transistor PD2-R, the third pass gate transistor PG2A and the fourth pass gate transistor PG2B. In addition, the second interconnection layer 60B is located between the second gate structure G12 and the fifth gate structure G15 (or the sixth gate structure G16). In addition, the first interconnection layer 60A and the second interconnection layer 60B also belong to a part of the metal layer MD.

Refer to FIG. 3 for other features. For the sake of clarity, in FIG. 3, elements (such as voltage source Vcc, voltage source Vss, first word line WL1, second word line WL2, first bit line BL1, second bit line BL2, third bit line BL3 and fourth bit line BL4) connected to each metal layer MP, MD and contact plug CT are directly marked on each metal layer to clearly express the connection between each metal layer MP, MD and contact plug CT.

As can be seen from FIG. 3, the layout pattern of this embodiment also meets the following characteristics, so FIG. 3 provides a layout pattern with high symmetry, which can increase the quality of components.
1. The first pull-up transistor PU1 and the second pull-up transistor PU2 are aligned in the longitudinal direction (Y direction).
2. The first pull-up transistor PU1 and the second pull-up transistor PU2 span the same fin structure together, that is, the fin structure F1 in FIG. 3.
3. On the left and right sides of the first pull-up transistor PU1, there is a part of the first pull-down transistor PD1 respectively, that is, the left half first pull-down transistor PD1-L and the right half first pull-down transistor PD1-R, and the first pull-up transistor PU1 is aligned with the left half first pull-down transistor PD1-L and the right half first pull-down transistor PD1-R on the left and right sides in the X direction.
4. On the left and right sides of the second pull-up transistor PU2, there is a part of the second pull-down transistor PD2 respectively, that is, the left half second pull-down transistor PD2-L and the right half second pull-down transistor PD2-R, and the second pull-up transistor PU2 is aligned with the left half second pull-down transistor PD2-L and the right half second pull-down transistor PD2-R on the left and right sides in the X direction.
5. The first pass gate transistor PG1A, the left half first pull-down transistor PD1-L, the left half second pull-down transistor PD2-L and the third pass gate transistor PG2A are aligned in the longitudinal direction (Y direction).
6. The second pass gate transistor PG1B, the right half first pull-down transistor PD1-R, the right half second pull-down transistor PD2-R and the fourth pass gate transistor PG2B are aligned in the longitudinal direction (Y direction).
7. As shown in FIG. 3, the metal layer connected to the voltage source Vcc is defined as MD1, wherein the metal layer MD1 is located between the first gate structure G11 and the second gate structure G12.
8. As shown in FIG. 3, the two metal layers connected the voltage sources Vss are defined as MD2 and MD3, and the metal layers MD2 and MD3 are also located between the first gate structure G11 and the second gate structure G12.
9. As shown in FIG. 3, the metal layer connecting the first gate structure G11 and the first interconnection layer 60B is defined as MP1, wherein the metal layer MD3 is located between the metal layer MD1 and the metal layer MP1 when viewed in the X direction.
10. As shown in FIG. 3, the metal layer connecting the second gate structure G12 and the first interconnection layer 60A is defined as MP2, wherein the metal layer MD2 is located between the metal layer MD1 and the metal layer MP2 when viewed in the X direction.
11. In addition, the metal layer MP1 and the metal layer MP2 are located next to the boundary of the region R2 (indicated by the dashed line in FIG. 3), that is to say, for the metal layer MP1, there are no other patterns between the boundary of the region R2 and the metal layer MP1, and for the metal layer MP2, there are no other patterns between the boundary of the region R2 and the metal layer MP2.

Based on the above description and drawings, the present invention provides a layout pattern of static random access memory (SRAM) cells, please refer to FIG. 3, which at least includes an SRAM cell in a region R2, and the SRAM cell includes a plurality of fin structures F located on a substrate, and the plurality of fin structures F at least include a first fin structure F11, a second fin structure F12 and a third fin structure F13 arranged along a Y direction. A plurality of gate structures G are located on the substrate, and each gate structure G extends along an X direction. The gate structures G include a first gate structure G11, a second gate structure G12, a third gate structure G13, a fourth gate structure G14, a fifth gate structure G15 and a sixth gate structure G16, wherein the gate structures G span a plurality of fin structures F, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate, wherein the first pull-up transistor PU1 and the second pull-up transistor PU2 are aligned with each other in the Y direction when viewed from a top view.

In some embodiments of the present invention, the first pull-up transistor PU1 and the second pull-up transistor PU2 span the same fin structure among a plurality of fin structures F (that is, the first fin structure F11).

In some embodiments of the present invention, in which the first gate structure G11 spans the first fin structure F11 and constitutes the first pull-up transistor PU1, the first gate structure G11 spans the second fin structure F12 and constitutes a part of the first pull-down transistor PD1, the part of the first pull-down transistor PD1 is defined as a left half first pull-down transistor PD1-L, the first gate structure G11 spans the third fin structure F13 and constitutes another part of the first pull-down transistor PD1, the another part of the first pull-down transistor PD1 is defined as a right half first pull-down transistor PD1-R.

In some embodiments of the present invention, the first pull-up transistor PU1 is located between the left half first pull-down transistor PD1-L and the right half first pull-down transistor PD1-R along the X direction, and the first pull-up transistor PU1, the left half first pull-down transistor PD1-L and the right half first pull-down transistor PD1-R are aligned in the X direction.

In some embodiments of the present invention, the third gate structure G13 spans the second fin structure F12 and constitutes the first pass gate transistor PG1A, and the fifth gate structure G15 spans the second fin structure F12 and constitutes the third pass gate transistor PG2A, wherein when viewed along a Y direction, the first pass gate transistor PG1A, the third pass gate transistor PG2A and the left half first pull-down transistor PD1-L are aligned with each other, and the left half first pull-down transistor PD1-L is located between the first pass gate transistor PG1A and the third pass gate transistor PG2A.

In some embodiments of the present invention, wherein the second gate structure G12 spans the first fin structure F11 and constitutes a second pull-up transistor PU2, the second gate structure G12 spans the second fin structure F12 and constitutes a part of the second pull-down transistor PD2, the part of the second pull-down transistor PD2 is defined as a left half second pull-down transistor PD2-L, the second gate structure G12 spans the third fin structure F13 and constitutes another part of the second pull-down transistor PD2, the another part of the second pull-down transistor PD2 is defined as a right half second pull-down transistor PD2-R.

In some embodiments of the present invention, the second pull-up transistor PU2 is located between the left half second pull-down transistor PD2-L and the right half second pull-down transistor PD2-R along the X direction, and the second pull-up transistor PU2, the left half second pull-down transistor PD2-L and the right half second pull-down transistor PD2-R are aligned in the X direction.

In some embodiments of the present invention, it further includes a Vcc metal layer MD1 and two Vss metal layers MD2 and MD3, wherein, from a top view, the Vcc metal layer MD1 and the two Vss metal layers MD2 and MD3 are located between the first gate structure G11 and the second gate structure G12.

In some embodiments of the present invention, the Vcc metal layer MD1 and the two Vss metal layers MD2 and MD3 are aligned with each other along the X direction.

In some embodiments of the present invention, the first gate structure G11, the second gate structure G12, the third gate structure G13 and the fifth gate structure G15 all span the second fin structure F12, and the first gate structure G11, the second gate structure G12, the fourth gate structure G14 and the sixth gate structure G16 all span the third fin structure F13.

The invention also provides a method for manufacturing layout patterns of static random access memory (SRAM) cells, which at least comprises forming an SRAM cell in a region R2, wherein the SRAM cell comprises a plurality of fin structures F located on a substrate, and the plurality of fin structures F at least comprise a first fin structure F11, a second fin structure F12 and a third fin structure F13 arranged along a Y direction. A plurality of gate structures G are located on the substrate, and each gate structure extends along an X direction. The gate structures G include a first gate structure G11, a second gate structure G12, a third gate structure G13, a fourth gate structure G14, a fifth gate structure G15 and a sixth gate structure G16, wherein the gate structures G span a plurality of fin structures F, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate, wherein the first pull-up transistor PU1 and the second pull-up transistor PU2 are aligned with each other in the Y direction when viewed from a top view.

To sum up, in one embodiment of the present invention, a layout pattern of SRAM cells with high symmetry is proposed, especially for each pass gate transistor, the surrounding environment of each pass gate transistor is approximately the same, for example, the distance from the fin structure spanned by each pass gate transistor to the adjacent fin structure is almost the same, so the current of each pass gate transistor of the SRAM of this embodiment approaches the same, which can improve the quality of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout pattern of static random access memory (SRAM) cells, at least comprising:
a region comprises an SRAM cell, wherein the SRAM cell includes:
a plurality of fin structures located on a substrate, and the plurality of fin structures at least comprise a first fin structure, a second fin structure and a third fin structure arranged along a Y direction;
a plurality of gate structures located on the substrate, and each gate structure extends along an X direction, wherein the gate structures include a first gate structure, a second gate structure, a third gate structure, a fourth gate structure, a fifth gate structure and a sixth gate structure, wherein the gate structures span the fin structures, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate;
wherein when viewed from a top view, the first pull-up transistor PU1 and the second pull-up transistor PU2 are aligned with each other in the Y direction.

2. The layout pattern of the SRAM cell according to claim 1, wherein the first pull-up transistor PU1 and the second pull-up transistor PU2 span the same fin structure of the plurality of fin structures.

3. The layout pattern of the SRAM cell according to claim 1, wherein the first gate structure spans the first fin structure and constitutes the first pull-up transistor PU1, and the first gate structure spans the second fin structure and constitutes a part of the first pull-down transistor PD1, the part of the first pull-down transistor PD1 is defined as a left half first pull-down transistor PD1-L, the first gate structure spans the third fin structure and constitutes another part of the first pull-down transistor PD1, the another part of the first pull-down transistor PD1 is defined as a right half first pull-down transistor PD1-R.

4. The layout pattern of the SRAM cell according to claim 3, wherein the first pull-up transistor PU1 is located between the left half first pull-down transistor PD1-L and the right half first pull-down transistor PD1-R along the X direction, and the first pull-up transistor PU1, the left half first pull-down transistor PD1-L and the right half first pull-down transistor PD1-R are aligned in the X direction.

5. The layout pattern of the SRAM cell according to claim 3, wherein the third gate structure spans the second fin structure and constitutes the first pass gate transistor PG1A, the fifth gate structure spans the second fin structure and constitutes the third pass gate transistor PG2A, wherein when viewed along a Y direction, the first pass gate transistor PG1A, the third pass gate transistor PG2A and the left half first pull-down transistor PD1-L are aligned with each other, and the left half first pull-down transistor PD1-L is located between the first pass gate transistor PG1A and the third pass gate transistor PG2A.

6. The layout pattern of the SRAM cell according to claim 1, wherein the second gate structure spans the first fin structure and constitutes the second pull-up transistor PU2, the second gate structure spans the second fin structure and constitutes a part of the second pull-down transistor PD2, the part of the second pull-down transistor PD2 is defined as a left half second pull-down transistor PD2-L, the second gate structure spans the third fin structure and constitutes another part of the second pull-down transistor PD2, the another part of the second pull-down transistor PD2 is defined as a right half second pull-down transistor PD2-R.

7. The layout pattern of the SRAM cell according to claim 6, wherein the second pull-up transistor PU2 is located between the left half second pull-down transistor PD2-L and the right half second pull-down transistor PD2-R along the X direction, and the second pull-up transistor PU2, the left half second pull-down transistor PD2-L and the right half second pull-down transistor PD2-R are aligned in the X direction.

8. The layout pattern of the SRAM cell according to claim 1, further comprising a Vcc metal layer and two Vss metal layers, wherein the Vcc metal layer and the two Vss metal layers are located between the first gate structure and the second gate structure from a top view.

9. The layout pattern of the SRAM cell according to claim 8, wherein the Vcc metal layer and the two Vss metal layers are aligned with each other along the X direction.

10. The layout pattern of the SRAM cell according to claim 1, wherein the first gate structure, the second gate structure, the third gate structure and the fifth gate structure all span the second fin structure, and the first gate structure, the second gate structure, the fourth gate structure and the sixth gate structure all span the third fin structure.

11. A method for manufacturing a layout pattern of a static random access memory (SRAM) cell, at least comprising:
forming an SRAM cell in a region, wherein the SRAM cell includes:
a plurality of fin structures located on a substrate, and the plurality of fin structures at least comprise a first fin structure, a second fin structure and a third fin structure arranged along a Y direction;
a plurality of gate structures located on the substrate, and each gate structure extends along an X direction, wherein the gate structures include a first gate structure, a second gate structure, a third gate structure, a fourth gate structure, a fifth gate structure and a sixth gate structure, wherein the gate structures span the fin structures, so as to form a first pull-up transistor PU1, a second pull-up transistor PU2, a first pull-down transistor PD1, a second pull-down transistor PD2, a first pass gate transistor PG1A, a second pass gate transistor PG1B, a third pass gate transistor PG2A and a fourth pass gate transistor PG2B located on the substrate;
wherein when viewed from a top view, the first pull-up transistor PU1 and the second pull-up transistor PU2 are aligned with each other in the Y direction.

12. The method for manufacturing the layout pattern of the SRAM cell according to claim 11, wherein the first pull-up transistor PU1 and the second pull-up transistor PU2 span the same fin structure of the plurality of fin structures.

13. The method for manufacturing the layout pattern of the SRAM cell according to claim 11, wherein the first gate structure spans the first fin structure and constitutes the first pull-up transistor PU1, and the first gate structure spans the second fin structure and constitutes a part of the first pull-down transistor PD1, the part of the first pull-down transistor PD1 is defined as a left half first pull-down transistor PD1-L, the first gate structure spans the third fin structure and constitutes another part of the first pull-down transistor PD1, the another part of the first pull-down transistor PD1 is defined as a right half first pull-down transistor PD1-R.

14. The method for manufacturing the layout pattern of the SRAM cell according to claim 13, wherein the first pull-up transistor PU1 is located between the left half first pull-down transistor PD1-L and the right half first pull-down transistor PD1-R along the X direction, and the first pull-up transistor PU1, the left half first pull-down transistor PD1-L and the right half first pull-down transistor PD1-R are aligned in the X direction.

15. The method for manufacturing the layout pattern of the SRAM cell according to claim 13, wherein the third gate structure spans the second fin structure and constitutes the first pass gate transistor PG1A, the fifth gate structure spans the second fin structure and constitutes the third pass gate transistor PG2A, wherein when viewed along a Y direction, the first pass gate transistor PG1A, the third pass gate transistor PG2A and the left half first pull-down transistor PD1-L are aligned with each other, and the left half first pull-down transistor PD1-L is located between the first pass gate transistor PG1A and the third pass gate transistor PG2A.

16. The method for manufacturing the layout pattern of the SRAM cell according to claim 11, wherein the second gate structure spans the first fin structure and constitutes the second pull-up transistor PU2, the second gate structure spans the second fin structure and constitutes a part of the second pull-down transistor PD2, the part of the second pull-down transistor PD2 is defined as a left half second pull-down transistor PD2-L, the second gate structure spans the third fin structure and constitutes another part of the second pull-down transistor PD2, the another part of the second pull-down transistor PD2 is defined as a right half second pull-down transistor PD2-R.

17. The method for manufacturing the layout pattern of the SRAM cell according to claim 16, wherein the second pull-up transistor PU2 is located between the left half second pull-down transistor PD2-L and the right half second pull-down transistor PD2-R along the X direction, and the second pull-up transistor PU2, the left half second pull-down transistor PD2-L and the right half second pull-down transistor PD2-R are aligned in the X direction.

18. The method for manufacturing the layout pattern of the SRAM cell according to claim 11, further comprising forming a Vcc metal layer and two Vss metal layers, wherein the Vcc metal layer and the two Vss metal layers are located between the first gate structure and the second gate structure when viewed from a top view.

19. The method for manufacturing the layout pattern of the SRAM cell according to claim 18, wherein the Vcc metal layer and the Vss metal layers are aligned with each other along the X direction.

20. The method for manufacturing the layout pattern of the SRAM cell according to claim 11, wherein the first gate structure, the second gate structure, the third gate structure and the fifth gate structure all span the second fin structure, and the first gate structure, the second gate structure, the fourth gate structure and the sixth gate structure all span the third fin structure.
